(19) United States
(12) Patent Application Publication
(10) Pub. No.: US 2010/0022078 A1
(43) Pub. Date: Jan. 28, 2010

(54) Aluminum Inks and Methods of Making the Same, Methods for Depositing Aluminum Inks, and Films Formed by Printing and/or Depositing an Aluminum Ink

(76) Inventors: Joerg ROCKENBERGER, San Jose, CA (US); Fabio Zürcher, Brisbane, CA (US); Wenzhuo Guo, Cupertino, CA (US)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/509,351

(22) Filed: Jul. 24, 2009

Related U.S. Application Data
(60) Provisional application No. 61/083,502, filed on Jul. 24, 2008.

(51) Int. Cl. H01L 21/28; C09D 11/00; B05D 5/12; H01L 21/3205

(52) U.S. Cl. 438/585; 106/31.06; 427/123; 427/553; 438/674; 257/E21.19; 257/E21.295

(57) ABSTRACT

Aluminum metal ink compositions, methods of forming such compositions, and methods of forming aluminum metal layers and/or patterns are disclosed. The ink composition includes an aluminum metal precursor and an organic solvent. Conductive structures may be made using such ink compositions by printing or coating the aluminum precursor ink on a substrate (decomposing the aluminum metal precursors in the ink) and curing the composition. The present aluminum precursor inks provide aluminum films having high conductivity, and reduce the number of inks and printing steps needed to fabricate printed, integrated circuits.

### RELATED APPLICATIONS

This application claims the benefit of U.S. Provisional Application No. 61/083,502, filed Jul. 24, 2008 (Attorney Docket No. IDR0651), which is incorporated by reference herein in its entirety.

### FIELD OF THE INVENTION

The present invention generally relates to the field of metal inks and methods of making and using the same. More specifically, embodiments of the present invention pertain to aluminum ink compositions, methods of making such aluminum ink compositions, and methods of forming conductive layers using such aluminum ink compositions and devices formed therefrom.

### BACKGROUND

Printing technologies can provide an alternative method to relatively laborious, wasteful, and expensive lithographic techniques for the fabrication of electronic devices and/or integrated circuits. However, advanced techniques and materials that allow for the fabrication of relatively high-performance and/or low-cost integrated circuits on a variety of substrates using selective deposition, printing and/or imaging technologies are still desired. In printing processes, materials in the form of liquid inks may be selectively deposited (e.g., printed) using techniques such as inkjet printing, gravure printing, screen printing, etc. Because printed electronics is an emerging technology, a limited number of inks are commercially available, and such inks provide a limited number of materials for fabricating electronic devices. Therefore, there is a continued need to develop new inks that not only can be printed using different techniques, but that also expand the palette of materials for fabricating printed devices, thereby improving the performance and/or lowering the cost of the integrated circuits, and providing a variety of different process integration schemes.

In integrated circuits, the devices (e.g., TFT, capacitors, diodes, etc.) may contain metal lines and features, such as electrodes, metal interconnects, etc. Conventional semiconductor manufacturing processes utilize metals including copper, aluminum, tungsten, chromium, and molybdenum for metallization (e.g., gates, capacitors, interconnect lines, etc.). These metals typically combine good adhesion, conductivity and electromigration resistance with process integration advantages such as good etch capability, high temperature resistance, and reduced hillock formation. Additionally, certain metals such as aluminum offer particular advantages for integration processes utilizing UV lasers for silicon crystallization and/or dopant activation. In particular, in a self-aligned gate mask process, the metal gate can act as a mask for dopant activation using laser irradiation (see, e.g., U.S. patent application Ser. No. 11/203,563 [Atty. Docket No. IDR0213], the relevant portions of which are incorporated herein by reference). Correspondingly, the gate metal employed must have low absorbance and/or high reflectivity for the UV laser wavelength to avoid melting and possibly destroying the gate metal during the laser processing.

Printed electronics offer the potential to reduce the processing cost of conventional semiconductor manufacturing, by additive printing of metal, semiconductor, and/or dielectric inks. Typical metal inks employed are mostly limited to silver, gold, palladium, cobalt, nickel and copper, due to the difficulties encountered in preparing suitable precursors and formulating inks of more conventional metals used in conventional device manufacturing. In addition, the use of silver or gold as a gate metal in a self-aligned gate mask process using laser irradiation for dopant activation is not possible, as silver absorbs the UV light and melts and/or is ablated, and gold is prohibitively expensive for such use.

Therefore, there is significant motivation within the integrated circuit manufacturing industry (including the display, photovoltaic, and flexible circuit manufacturing and/or fabrication industries) to develop an ink formulation of a more conventional metal used in semiconductor manufacturing, such as aluminum. The present application discloses aluminum ink compounds and formulations, methods of making aluminum compounds and ink formulations, as well as deposition processes for forming aluminum films, printed features, lines, etc. from the aluminum inks.

### SUMMARY OF THE INVENTION

Embodiments of the present invention relate to aluminum ink compositions, methods of forming aluminum ink compositions, and methods of forming conductive layers, such as metal electrode layers, from the aluminum inks and devices formed therefrom.

A first aspect of the present invention concerns an ink composition comprising an aluminum metal precursor compound, and methods of making the same. The aluminum inks of the present invention may allow for a reduction in the number of lithography and etching steps in conventional metallization processes. Additionally, by forming gates, interconnect wirings, and other structures by printing or coating the aluminum inks, silicon crystallization and dopant activation using ultraviolet (UV) lasers can be carried out without an extra mask, since an aluminum gate has a low absorbance and a high reflectivity for UV laser wavelengths. Thus, the number of process steps for fabricating integrated circuits (including display, photovoltaic, and flexible circuits) may be further reduced or minimized in such technology.

In one embodiment, the metal ink composition comprises an aluminum metal precursor (e.g., an aluminum hydride, such as AlH₃, an organoalanes, a complex of AlH₃ or an organoalane, etc.), and an organic solvent. The ink may also include one or more additives (e.g., surfactants, adhesion promoters, and/or catalysts) to stabilize the formulation and/or to alter its physical and chemical properties for different deposition processes. The aluminum precursor may be present in an amount from about 0.01 to 100% by weight (preferably about 0.5 to 50 wt %, and more preferably about 1 to 10 wt %) of the ink. The solvent may be present in an amount from about 0.1 to 99.9% by weight (preferably about 50 to 95 wt %) of the ink. Optionally, the additives may be present in an amount from about 0.1 to 10% by weight (preferably about 0.1 to 5 wt %) of the ink.

The aluminum ink composition may be made by combining (i) an aluminum metal precursor and, optionally, (ii) one or more additives (e.g., surfactants, adhesion promoters and/or catalysts, etc.) with one or more solvents adapted to facilitate coating and/or printing of the composition, and dissolving and/or suspending the component(s) in the solvent(s). In general, aluminum ink compositions suitable for use with the present method comprise an aluminum hydride, an organoaluminum compound, and/or a derivative (e.g., a donor complex) thereof.

Another aspect of the present invention concerns a method of forming conductive structures from the metal ink compositions described herein. According to one general embodiment, the method for forming a metal layer (e.g., an electrode or interconnect layer in an integrated circuit or display TFT backplane) comprises (a) depositing (e.g., by printing) an aluminum ink composition comprising an aluminum metal precursor on a substrate (e.g., a semiconductor or other substrate surface), (b) substantially decomposing the aluminum precursor to form an aluminum hydride polymer and/or aluminum metal by heating and/or irradiating the aluminum ink composition and/or decomposed aluminum precursor, and (c) if necessary, curing the aluminum metal and/or the aluminum hydride polymer to form an aluminum metal layer.

The present invention addresses the need to develop aluminum inks for forming gates, electrodes, interconnects, and other structures in electronic devices. Several methods for forming aluminum device layers and electronic devices are described herein. In a process for making printed electronic devices, the present ink may reduce or minimize the number of masking, lithography, and etching steps in fabricating printed integrated circuits and/or structures therein. These and other advantages of the present invention will become readily apparent from the detailed description of preferred embodiments below.

### BRIEF DESCRIPTION OF THE DRAWINGS

FIGS. 1A-1C show cross-sectional views of an exemplary method of making a thin film transistor including an aluminum gate electrode from a deposited aluminum precursor ink. FIG. 1C shows a completed thin film transistor.

FIGS. 2A-2C show cross-sectional views of an exemplary method of making a capacitor, including an aluminum upper capacitor electrode and/or lower capacitor electrode from a deposited aluminum precursor ink. FIG. 2C shows a completed capacitor. FIG. 2B shows a completed capacitor of an alternative embodiment.

FIGS. 3A-3D show cross-sectional views of an exemplary method of making a diode, including an aluminum upper electrode formed from a deposited aluminum precursor ink. FIG. 3D shows a completed diode.

FIGS. 4A-4B show cross-sectional views of an exemplary method of making an aluminum interconnect wiring from a deposited aluminum precursor ink. FIG. 4B shows a completed aluminum interconnect wiring.

### DETAILED DESCRIPTION OF THE PREFERRED EMBODIMENTS

Reference will now be made in detail to various embodiments of the invention, examples of which are illustrated in the accompanying drawings. While the invention will be described in conjunction with exemplary embodiments, it will be understood that the description is not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. In addition, it should be understood that the possible permutations and combinations described herein are not meant to limit the invention. Specifically, variations that are not inconsistent may be mixed and matched as desired.

For the sake of convenience and simplicity, the terms “coupled to,” “connected to,” and “in communication with” mean direct or indirect coupling, connection or communication, unless the context clearly indicates otherwise. These terms are generally used interchangeably herein, but are generally given their art-recognized meanings. Furthermore, the terms “shape,” “feature,” “line,” “pattern,” and or other such terms may be used interchangeably, and use of one such terms will generally include the other terms, although the meaning of the term should be taken from the context in which it is used. Also, for convenience and simplicity, the terms “part,” “portion,” and “region” may be used interchangeably, but these terms are also generally given their art-recognized meanings. The term “(semi)conductor,” “(semi)conductive,” “(semi)conducting” and grammatical equivalents thereof refer to materials, precursors, layers, features or other species or structures that are conductive and/or semiconductive.

In the present application, the term “deposit” (and grammatical variations thereof) is intended to encompass all forms of deposition, including blanket deposition (e.g., CVD and PVD), coating, and printing. In various embodiments, coating may comprise spin-coating, spray-coating, slit coating, extrusion coating, meniscus coating, dip coating, and/or pen-coating the metal ink formulation onto the substrate. In other embodiments, printing may comprise inkjetting, gravure printing, offset printing, flexographic printing, screen printing, slit extruding, microspotting and/or selectively pen-coating the metal ink formulation onto the substrate. In general, coating refers to a process where the ink or other material is deposited on substantially the entire substrate, whereas printing generally refers to a process where the ink or other material is deposited in a predetermined pattern in certain areas of the substrate. Also, unless indicated otherwise from the context of its use herein, the terms “known,” “fixed,” “given,” “certain” and “predetermined” generally refer to a value, quantity, parameter, constraint, condition, state, process, procedure, method, practice, or combination thereof that is, in theory, variable, but is typically set in advance and not varied thereafter when in use. In addition, the term “doped” refers to a material that is doped with a substantially controllable dose of any known dopant (e.g., lightly doped, heavily doped, or doped at any doping level in between).

The invention, in its various aspects, will be explained in greater detail below with regard to exemplary embodiments.

Exemplary Aluminum Ink Compositions

According to the embodiments of the present invention, an ink composition generally comprises an aluminum metal precursor in an amount of from about 0.01 to 100% by weight (e.g., about 0.5 to 50 wt %, about 1 to 10 wt %, or about 1 to 5 wt %, or any other range of values between 0.01 and 100 wt %) of the ink, and an organic solvent present in an amount from about 0.1 to 99.9% by weight or any range of values therein (e.g., about 75 to 98 wt %, 50 to 95 wt %, or any other range of values within 0.1 and 99.9 wt %) of the ink. Optionally, one or more additives (e.g., one or more surfactants, surface tension modifying agents, binding agents, thickening agents, photosensitizers, etc.) may be present (individually or in total) in an amount of from 0.1 to 10% by weight (e.g., about 0.1 to 5 wt % or any other range of values therein) of the ink. The aluminum ink composition(s) of the present invention may be suitable for forming a gate electrode, a source electrode, or a drain electrode of a thin film transistor (TFT), an interconnect, or an electrode or other structure in a capacitor, diode, and/or other electronic device.

In exemplary embodiments, the aluminum precursor comprises substituted and/or unsubstituted aluminum hydride compounds. For example, in one embodiment, the aluminum metal precursor comprises AlH₃. In other examples, the aluminum metal precursor comprises an aluminum hydride substituted with one or more organic side chains (e.g., an alkyl-substituted aluminum hydride such as isobutylaluminum hydride, dimethylaluminum hydride, etc.) and/or a trialkyl aluminum species (e.g., triisobutyl aluminum). In further examples, the aluminum metal precursor may further include one or more ligands complexed with the substituted and/or unsubstituted aluminum hydride. More specifically, the aluminum precursor may include one or two ligands selected from amines, phosphines, ethers, and/or other appropriate (donor-type) ligands. However, the present invention is not limited to the examples provided herein.

For example, the aluminum precursor ink composition may include one or more of the following aluminum precursors: 1) aluminum hydrides, 2) C₁-C₆ alkyl-substituted aluminum hydrides such as isobutylaluminum hydride, triisobutylaluminum, and dimethylaluminum hydride, and 3) complexes of aluminum hydride with one or two ligands, such as an amine, a phosphine, and/or an ether. In particular, the complexes may include an aluminum hydride complexed with a low molecular weight C₁-C₆ alkyl-substituted amine such as a trialkylamine (e.g., trimethylamine alane, triethylamine alane, tripropylamine alane, dimethylethylamine alane, etc.). However, the formulation is not limited as such. For instance, the aluminum hydrides may be complexed with bidentate ligands, such as ethylenediamine, tetramethyl hydrazine, 2,2-bipyridine, 1,2-bis(diphenylphosphino)ethane, 1,3-bis(diphenylphosphino)propane, etc. On the other hand, the aluminum hydrides can include polymeric AlH₃ to the extent that it can be handled similarly to a nanoparticle suspension in an inert solvent (such as an alkane or cycloalkane) or can be passivated (see the discussion herein) or derivatized. In other embodiments, a single ink formulation may comprise a plurality of aluminum metal precursors as described herein.

Thus, the aluminum metal precursor formulations suitable for use in the present aluminum ink composition include compounds or complexes having the general formula [R¹_{y}A]ₓAlR²₃, where each instance of A is independently a Group VA element (e.g., N, P, As, or Sb) or a Group VI element (e.g., O, S, Se, or Te); x is 1 or 2; y is 2 or 3; and R¹ and R² are independently H, linear, bridged or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group. Generally, y is 2 when A is a Group VI element and y is 3 when A is a Group VA element. These precursors may be solids or liquids. The precursors may be decomposed at temperatures of about 400° C. or less (e.g., about 350 to 400° C., about 250 to 350° C., about 100 to 250° C., or any other range of values less than 400° C.). Such compounds or complexes are known to decompose readily at temperatures as low as 100° C. to yield aluminum films with high purity.

In general, amine ligand complexes of aluminum hydrides are suitable as aluminum metal precursors in the present aluminum ink composition. For example, in reference to the formula [R¹₃N]AlR²₃, and each instance of R¹ in the aluminum metal precursor may be independently H or a linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group. Alternatively, two R¹ groups taken together with the N atom may form an aliphatic or aromatic cyclic ring. In embodiments of the aluminum metal precursor that have amine ligands, appropriate amine ligands include monoalkyl-, dialkyl-, and trialkylamine complexes, piperidine or pyrrolidone complexes, etc. Exemplary amine ligand complexes of aluminum hydrides include aluminum hydride-trialkyl amine complexes, where the trialkyl amine is selected from the group consisting of trimethylamine, triethylamine, tri-n-propylamine, triisopropylamine, methyl diethylamine, dimethyl ethylamine, n-propyldimethylamine, and isopropyl diethylamine. Exemplary aluminum metal precursors include trimethylamine alane, triethylamine alane, dimethylaluminum hydride, or mixtures thereof.

In other embodiments, the aluminum metal precursor may include complexes of aluminum hydride with two amine and/or phosphine ligands. For example, the aluminum metal precursor may have the formula [R¹₃A]₂AlR²₃, where the 2 instances of A are independently N or P, and each instance of R¹ is independently H or a linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aryl group. The amine ligand may include an amine compound as described above. The phosphine ligand may have the formula PR¹₃, where R¹ is as described herein. Examples of the phosphine ligand include a monoalkyl-, dialkyl-, or a trialkylphosphine. Specific examples of phosphines include trimethylphosphine (P(CH₃)₃), tri-t-butyl phosphine (P(C(CH₃)₃)₃), triphenylphosphine (P(C₆H₅)₃), triisopropylphosphine P(CH(CH₃)₂)₃, or tricyclohexylphosphine (P(C₆H₁₁)₃). In an exemplary embodiment of the aluminum metal precursor ink, the aluminum metal precursor comprises a compound having the formula H₃Al(N[CH₃]₃)(P[C(CH₃)₃]₃).

In alternative embodiments, the aluminum metal precursor may include complexes of aluminum hydride with an ether and/or other ligand. For example, the aluminum metal precursor may have the formula R²₃Al(AR¹₃)(OR³₂) or R²₃A(OR³₂). The ligand represented by the formula AR¹₃ may include an amine or a phosphine ligand, as described above. The formula OR³₂ represents an ether ligand. The R³ groups of the ether ligand may independently be H, linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group. Alternatively, two R³ groups taken together with the O atom may form an aliphatic or aromatic cyclic ring. Preferably, the R³ groups of the ether ligand are C₁-C₄ alkyl groups. Examples of appropriate ether ligands include diethyl ether, di-n-propyl ether, di-n-butyl ether, di-isopropyl ether, di-t-butyl ether, methyl-butyl ether, n-propyl-n-butyl ether, methyl-t-butyl ether, ethyl-t-butyl ether, tetrahydrofuran, or mixtures thereof. In an exemplary embodiment of the aluminum metal precursor ink, the aluminum metal precursor comprises a compound having the formula H₃Al(N[CH₃]₃)(O(CH₂CH₃)₂).

The organic solvent(s) in the ink composition may be selected from those solvents known to stabilize aluminum hydride (e.g., one or more inert solvents such as aliphatic, alicyclic, or aromatic hydrocarbons). For example, the solvent may be selected from saturated hydrocarbons (e.g., a C₅-C₁₂ alkane [such as hexane, octane decane, etc.]), unsaturated hydrocarbons (e.g., a C₄-C₁₂ alkene, a C₄-C₁₂ alkyne, etc.), cyclic hydrocarbons (e.g., a C₆-C₁₄ monocycloalkane [such as cyclohexane, cyclooctane, cyclodecane, etc.], a C₁₀-C₁₄ bicycloalkane [such as cis-decalin, trans-decalin, etc.], or a C₁₀-C₁₄ polycycloalkane, each of which may be substituted with from 1 to 2q C₁-C₄ alkyl or from 1 to q C₁-C₄ alkoxy substituents, where q is the number of carbon atoms in the cycloalkane ring), aromatic hydrocarbons (e.g., toluene, benzene, xylene, mesitylene, tert-butyltoluene, tetralin, cyclohexylbenzene, etc.), halogenated hydrocarbons, ethers (e.g., a C₄-C₂₀ cyclic or alicyclic ether, C₄-C₂₀ linear ethers, dipropylene glycol butyl ether, propylene glycol monoethyl ether, etc.), polyethers (e.g., diglyme, etc.), amines (e.g., an amine having from one to three C₁-C₁₂ alkyl groups), alcohols (e.g., C₁-C₁₀ alcohol [such as 3-octanol, 2-ethylhexanol, etc.], C₁-C₈ mono- or diol, a C₁-C₄ alkoxy-substituted C₁-C₆ alkanol, a C₁-C₆ alcohol substituted with a C₃-C₅ heterocyclic group, a C₁-C₄ alkoxy-substituted C₁-C₆ alkanol, a C₁-C₆ alcohol substituted with a C₃-C₅ heterocyclic group, alpha-terpineol, dihydroterpineol, etc.), glycols, thiols, phosphates, silicones, sulfoxides, fatty acids, terpenes, terpineols and/or combinations thereof. In other embodiments, the organic solvent may comprise mineral spirits, pyridine, methicones, cyclomethicones (e.g., cyclo-([Me₂Si]O)₃, cyclo-([Me₂Si]O)₄, etc.), and/or combinations thereof. In one embodiment, the solvent is an aliphatic, alicyclic or aromatic ether such as diethylether, dibutylether, dipropylether, diphenylether, dibenzylether, methylphenylether, tetrahydrofuran, dioxane, etc. Where the aluminum precursor compound comprises a trialkyl aluminum compound or other compound where the aluminum atom is not bonded to a hydrogen, the solvent may also include an amide, a lactone, a fatty acid, a ketone (e.g., acetone, methyl ethyl ketone, cyclohexanone, etc.), an ester (e.g., ethyl acetate, ethyl lactate, etc.), a nitrile, or a mixture thereof.

In an exemplary embodiment, the organic solvent or solvent mixture stabilizes the aluminum precursor formulation and, alone or in conjunction with other material(s) in the formulation, provides a predetermined viscosity, surface tension, and/or evaporation rate that facilitates coating and/or printing (e.g., inkjetting) of the ink composition. For example, the organic solvent may be added in a volume (or volume ratio) sufficient to provide a viscosity of about 2 to 100 cP (e.g., 2 to 15 cP or any other range of values therein) and/or a surface tension of at least 20 dynes/cm (e.g., at least 25 dynes/cm, from 25 dynes/cm to about 100 dynes/cm, or any other range of values of at least 20 dynes/cm). In other examples, the organic solvent may be added in a volume or volume ratio sufficient to formulate a paste suitable for screen printing (e.g., a paste having a viscosity greater than or about 10,000 cP) or to formulate an ink suitable for gravure printing (e.g., an ink having a viscosity up to 200 cP).

The aluminum ink composition may further comprise one or more additives, including a promoter compound that improves the adhesion of the aluminum precursor ink composition and promotes the nucleation of the aluminum metal on a substrate. Alternatively, the promoter compound can be printed, coated, or deposited onto a substrate prior to depositing an aluminum ink. The promoter compound may also catalyze the decomposition of the aluminum hydride(s) in the ink composition once the ink composition is printed or coated on a substrate (e.g., during later decomposition and curing processes). In various embodiments, the promoter-catalyzed decomposition may allow the decomposition to occur at a temperature of up to about 100° C., and in some embodiments, in a range from about 15° C. to 40° C. (e.g., room temperature).

The aluminum precursor ink may further include such promoter/nucleation compound(s) in an amount of about 0.1 to about 50 wt. % or any range of values therein (e.g., 1 to 25% by weight, or 1 to 10% by weight). The promoter compounds may include compounds having the formula M¹Xₙ, wherein M¹ is Si or a metal selected from the group consisting of Hf, Nb, Ta, Ti, V, and Zr; n is 2, 3, 4, or 5; and each instance of X is independently F, Cl, Br, I, O, or a pseudohalide. Alternatively, the promoter compounds may include metal alkoxides and/or metal amides. The metal alkoxides and/or metal amides may include compounds having the formula M²(ZR⁴)ₘ, wherein M² is a metal selected from the group consisting of Hf, Nb, Ta, Ti, V, and Zr; Z is oxygen or nitrogen; R⁴ is a C₁-C₆ alkyl group; and m is 3, 4, or 5. Exemplary promoter compounds include TiCl₄, TiBr₄, SiCl₄, and Ti(OEt)₄ which are known to improve the adhesion and promote the nucleation of Al films formed on substrates. Other exemplary promoter compounds include VOCl₃, VOCl₂, SiCl₄, TiCl₄.2(OEt₂), TiCl₂(OEt₂)₂, TiCl₂(i-OC₃H₇)₂, Ti(BH₄)₂.2(OEt₂), or a mixture thereof.

In alternative embodiments, where the promoter compound is printed, coated, or deposited onto a substrate prior to depositing the aluminum ink, an ink comprising the promoter compound can be printed or coated onto the substrate, then after drying (and optionally, curing) the promoter ink, the aluminum precursor ink can be printed (e.g., inkjetted) or coated (e.g., spin-coated) over the promoter compound. The promoter compound may catalyze the decomposition of aluminum precursor(s) in the aluminum ink composition (e.g., after the ink is printed or coated over the promoter/nucleation compounds) during a heating and/or irradiation process. Alternatively, Al metal can be electrolessly plated onto a dried and/or cured promoter compound in a bath comprising the aluminum hydride precursor.

Other metals or metal precursors may be added to the present aluminum ink formulation. For example, to reduce spiking in silicon-containing features onto which the present ink composition may be deposited, the ink may contain a small amount (e.g., about 2 at % based on silicon and aluminum atoms) of Si nanoparticles and/or one or more silanes (e.g., a cyclosilane having 5 or more Si atoms, a linear or branched silane having from 7 to 15 Si atoms, an oligo- or polysilane having 15 or more Si atoms to which substantially only H and/or a halogen is bound, etc.). In addition, to reduce electromigration and/or to suppress hillock formation, nanoparticles and/or organometallic compounds of Cu and/or Ti may be added in amounts up to about 4 at %. (e.g., from about 0.5 to about 2.0 at %).

The aluminum precursor ink may further comprise one or more other ink additives such as a surfactant, which may be present in an amount of about 0.1 to 10 wt % or any range of values therein (e.g., about 0.1 to 5 wt %). The surfactant may comprise an amine, an amine oxide, a quaternary ammonium salt, a betaine, a sulfobetaine, an ether, a polyglycol, a polyether, a polymer, a phosphine, a phosphate, a sulfonic acid, a sulfonate, a sulfate, and/or a silicone. In various implementations comprising a surfactant, suitable surfactants may include a tri-C₁-C₂₀ alkyl-substituted amine, a tri-C₁-C₂₀ alkyl-substituted amine oxide, a tetra-C₁-C₂₀ alkyl-substituted quaternary ammonium salt, a conventional betaine, a conventional sulfobetaine, a polyglycol of the formula H—(—OCH₂CH₂—)ₐ—OH (where 2≦a≦4), a polyether of the formula R⁵—(—OCH₂CH₂—)ₐ—OR⁶ (where R⁵ and R⁶ are independently a C₁-C₄ alkyl group), a C₄-C₂₀ branched or unbranched, a tri-C₁-C₂₀ alkyl- or triaryl-substituted phosphine (such as trimethyl phosphine, triethyl phosphine, or triphenyl phosphine), a tri-C₁-C₂₀ alkyl- or triaryl-substituted phosphate, a di-C₁-C₂₀ alkyl- or diaryl-substituted phosphate salt, an aryl or C₄-C₂₀ branched or unbranched, saturated or unsaturated aliphatic sulfonic acid, an aryl or C₄-C₂₀ branched or unbranched, saturated or unsaturated aliphatic sulfonate, and/or a conventional silicone. Where the aluminum precursor comprises a trialkyl aluminum compound or other compound where the aluminum atom is not bonded to a hydrogen, the solvent may also include one or more organic esters, ketones of the formula R⁷(C═O)R⁸ (where R⁷ and R⁸ are independently a C₆-C₁₀ aryl group), saturated or unsaturated C₄-C₂₀ aliphatic carboxylic acid ester of a C₁-C₄ alcohol, a C₄-C₂₀ aliphatic carboxylic acid thioester of a C₁-C₄ thiol, or mixtures thereof.

Exemplary Methods of Making an Aluminum Ink Composition

Another aspect of the present invention concerns method of making an aluminum ink formulation. The present aluminum ink compositions can be formulated by dissolving the aluminum metal precursors (as described in paragraphs [0022]-[0027]) in solvents known to stabilize an aluminum hydride. In general, an exemplary ink formulation may be made by combining (i) one or more aluminum metal precursors suitable for use in the present aluminum ink composition (for example, a compound having the general formula [R¹_{y}A]ₓAlR²₃, as described above), and (ii) one or more solvents (e.g., organic solvents) adapted to facilitate coating/printing of the composition, and dissolving or suspending the aluminum precursor(s) in the solvent(s). Any additional components (e.g., promoter compounds, surfactants, etc.) may be added to the solution with the aluminum precursors or after the aluminum precursors have been dissolved or suspended. The solvent and the aluminum metal precursors may be mixed sufficiently to dissolve or suspend the components in the ink formulation so that they are substantial homogeneous for a sufficient length of time to print or otherwise deposit the ink formulation. In exemplary embodiments, the aluminum metal precursor(s) may include one or more of the following: 1) an aluminum hydride, 2) a C₁-C₆ alkyl-substituted aluminum hydride (e.g., isobutylaluminum hydride, triisobutylaluminum, and dimethylaluminum hydride), and/or 3) a complex of a substituted or unsubstituted aluminum hydride with one or more ligands, such as an amine, a phosphine, and/or an ether. In particular, the complexes may include an aluminum hydride complexed with a low molecular weight C₁-C₆ alkyl-substituted amine such as a trialkylamine (e.g., trimethylamine alane, triethylamine alane, tripropylamine alane, dimethylethylamine alane, etc.).

Aluminum hydride can be prepared by the reaction of lithium aluminum hydride (LiAlH₄) with AlCl₃ in an ether solution (3 LiAlH₄+AlCl₃→4 AlH₃+3 LiCl). Typically, a 2 to 10 fold excess of LiAlH₄ is employed. The ether solution may comprise one or more aliphatic ethers, examples of which include diethyl ether, di-n-propyl ether, di-n-butyl ether, di-isopropyl ether, di-t-butyl ether, methyl-butyl ether, n-propyl-n-butyl ether, methyl-t-butyl ether, ethyl-t-butyl ether, or mixtures thereof. After the reaction is complete, precipitated LiCl is removed by filtration and an AlH₃·ether complex is isolated by distillation. To ensure high purity and improved consistency of the reaction, commercially available LiAlH₄ ether solution (e.g., 1.0 M in diethyl ether [Product No. 212792] from Sigma-Aldrich Co., St. Louis, Mo.) is preferably purified before use (e.g., by [re]crystallization of the LiAlH₄ therein). Also, the AlCl₃ is preferably freshly sublimed before use.

Alternatively, aluminum hydride may be prepared by reacting lithium aluminum hydride with beryllium chloride (2 LiAlH₄+BeCl₂→2 AlH₃+LiBeH₂Cl₂) in diethyl ether at a temperature of about 18° C. to 50° C., or with sulfuric acid (2 LiAlH₄+H₂SO₄→2 AlH₃+Li₂SO₄+2 H₂) in diethyl ether at a temperature of about 90° C. or less. After the reaction is complete, precipitated LiBeH₂Cl₂, Li₂SO₄, and/or LiCl can be removed by filtration, and the AlH₃ ether complex may be isolated by distillation.

Amine complexes of aluminum hydrides can be synthesized from lithium aluminum hydride (which may be purified before use) and an appropriate ammonium chloride salt (e.g., HN(CH₃)₃Cl, HN(C₂H₅)₃Cl, HN(CH₃)₂(C₂H₅)Cl, etc.). These precursor may be solids or liquids. Such complexes may decompose at temperatures between about 100 to 400° C. (e.g., about 100 to 200° C.) to yield aluminum films with high purity. Alternatively, amine complexes of aluminum hydrides are commercially available from various vendors (e.g., alane N,N-dimethylethylamine complex solution [Product No. 400386] from Sigma-Aldrich Co., St. Louis, Mo.; alane trimethylamine complex [Product No. OMAL008] from Gelest, Inc., Morrisville, Pa.; etc.).

The methods for synthesizing aluminum hydrides described above are examples and do not limit the scope of the substituted or unsubstituted aluminum hydrides and aluminum hydride complexes that may be included in the aluminum precursor inks described herein. Once prepared, the aluminum hydrides can be combined, mixed, dissolved and/or suspended in one or more solvents (e.g., organic solvents) adapted to facilitate coating/printing of the composition, as described herein.

In some embodiments, the method may further comprise adding one or more additives, such as a promoter compound (as described above in paragraphs [0030]-[0032]), a surface tension modifying agent, a surfactant, a binding agent, a thickening agent, a photosensitizer, etc., to the ink composition. Typical amounts of the additives in the composition are from 0.01 wt. % to 10 wt. % (e.g., in trace amounts, or from 0.1 wt. % to 5 wt. %, or any other range of values therein) of the composition. However, such additives may not be necessary. In fact, it may be advantageous to exclude the additives from the ink, particularly where such additional components include sufficiently high molar proportions of elements such as carbon, oxygen, sulfur, nitrogen, or halogens to adversely affect electrical properties of the resulting thin film. In exemplary embodiments, the composition is substantially free from components that may introduce impurity atoms or other species that may adversely affect the electrical properties of a thin film formed from the composition (e.g., carbon, nitrogen, alkali metals, etc.).

The components of the ink formulation may be combined in any order. The components may be mixed by mechanical stirring, magnetic stirring, blending, shaking or other form of physical agitation, etc. In some embodiments, the ink may be mixed or formulated under an inert atmosphere (e.g., Ar or N₂, preferably Ar) to avoid oxidation of some of the ink components and/or unacceptably high oxygen content in the films formed from the ink.

Exemplary Methods of Forming an Aluminum Metal Layer

In general, a metal layer may be formed by depositing (e.g., printing) an aluminum precursor ink composition (e.g., comprising an aluminum precursor, a solvent or solvent mixture, and optionally, a promoter compound as described above) on a substrate, then converting the Al precursor to Al metal. A method for forming a patterned metal film may comprise depositing the Al metal precursor on a substrate in a predetermined pattern, and converting the Al precursor to Al metal by heating, curing or irradiating the Al precursor. For example, converting the Al precursor to Al metal may comprise irradiating the deposited ink and/or heating the substrate with the Al precursor ink deposited thereon to a temperature sufficient to substantially decompose the Al metal precursor to form an aluminum hydride, an organoaluminum polymer and/or Al metal, and then curing the ink composition to form an aluminum metal layer. Thus, structures and/or features (e.g., electrodes, interconnect lines, capacitor plates, etc.) in electronic devices can be made by depositing (e.g., printing or coating) an aluminum precursor ink, heating and/or irradiating the ink, and curing the ink to form an aluminum metal layer on a substrate in a predetermined pattern.

The aluminum metal layer may be formed on any suitable substrate. The substrate generally comprises a mechanical support structure, which may be electrically inert or active, and which may include one or more predetermined physical, electrical and/or optical properties. Suitable electrically inert or inactive substrates may comprise a glass or other ceramic plate, disc, sheet or slip (e.g., comprising display-type glass, quartz, etc.), a dielectric and/or a plastic sheet or disc (e.g., a transparent plastic such a polycarbonate sheet, etc.), laminated variations thereof, etc. Alternatively, suitable electrically conductive substrates may comprise a semiconductor wafer or disc (e.g., a silicon wafer), a metal disc, sheet or foil (e.g., a metal film, metal sheet, and/or metal foil), etc. Any of the above-mentioned substrates may further include one or more buffer, passivation, planarization, mechanical support and/or insulating layers thereon. For example, the buffer, planarization and/or insulating layer may comprise a polyimide or other polymer layer or sheet, silicon dioxide and/or aluminum oxide, etc.

In embodiments comprising a metal substrate, the metal substrate may comprise a sheet, layer or foil of aluminum, titanium, copper, silver, chromium, molybdenum, tungsten, nickel, gold, palladium, platinum, zinc, iron, steel (e.g., stainless steel) or any alloy thereof. Suitable substrates are described in detail in co-pending U.S. patent application Ser. No. 11/888,949, filed Aug. 3, 2007 (Attorney Docket No. IDR0742), the relevant portions of which are incorporated herein by reference. The substrate may also include any number of previously fabricated device layers thereon and/or therein, such as conductive layers, dielectric layers, semiconducting layers, or combinations thereof.

In certain embodiments, the aluminum metal layer may be formed on a dielectric layer on the substrate. In such embodiments, the dielectric layer may be formed by any suitable method known in the art. The dielectric layer may comprise any suitable electrically insulating dielectric material. For example, the dielectric material may comprise oxide and/or nitride ceramics or glasses (e.g., silicon dioxide, silicon nitride, silicon oxynitride, aluminum oxide, tantalum oxide, zirconium oxide, etc.), polymers such as polysiloxanes, parylene, polyethylene, polypropylene, undoped polyimides, polycarbonates, polyamides, polyethers, copolymers thereof, fluorinated derivatives thereof, etc. In some embodiments, the dielectric layer may be an inorganic insulator. For example, the dielectric may comprise a metal oxide and/or nitride of the formula MₓO_{y}N_{z}, wherein M is silicon or a metal selected from the group consisting of aluminum, titanium, zirconium, tantalum, hafnium, vanadium, chromium, molybdenum, tungsten, rhodium, rhenium, iron, ruthenium, copper, zinc, indium, tin, lanthanide metals, actinide metals, and mixtures thereof. In embodiments comprising a conductive substrate, the dielectric may comprise a corresponding oxide of the metal used in the conductive substrate.

In embodiments that include a conductive substrate, the dielectric layer may be formed by oxidizing and/or nitriding the conductive substrate (or a liquid oxide/nitride precursor formed or deposited thereon), generally in an oxidizing and/or nitriding atmosphere. For example, the dielectric can be formed by anodic oxidation (see, e.g., U.S. Pat. Nos. 7,152,804 and 7,286,053, the relevant portions of which are incorporated by reference herein), oxidizing a liquid silane printed onto a metal and/or insulative substrate (e.g., stainless steel, aluminum foil, etc.), or by coating the substrate with another material (e.g., silicon, aluminum, chromium, hafnium, etc.) that can be oxidized or nitrided to form a dielectric. In other embodiments, the dielectric layer may be formed by blanket deposition or coating (e.g., spray coating, dip coating, blade coating, meniscus coating, slit coating, extrusion coating, pen-coating, microspotting, spin-coating, etc.) or a vacuum deposition method such as CVD, PECVD, LPCVD, sputter deposition, etc. In such embodiments, areas of the substrate may be subsequently patterned and/or exposed as desired by etching techniques known in the art.

Alternatively, the dielectric may be formed by depositing (e.g., by printing or chemical bath deposition processes) a dielectric precursor material (e.g., a SiO₂ precursor such as a tetraalkoxysilane, a cyclic siloxane such as c-([SiH(OH)])₅, or a silicon halide such as SiCl₄ or H₂SiF₆) and subsequently converting the precursor to a dielectric film (e.g., by drying, curing, and/or annealing, optionally in an oxidizing atmosphere). The dielectric layer may be formed by printing techniques known in the art (e.g., inkjet printing, gravure printing, screen printing, offset printing, flexography, syringe dispensing, microspotting, stenciling, stamping, pump dispensing, laser forward transfer, local laser CVD and/or pen-coating, etc.). In some embodiments, the dielectric layer may be selectively printed such that areas of the substrate (e.g., conductive substrate) are exposed. In the alternative, the dielectric layer may be printed to cover the entire substrate, and then etched using subsequently formed structures as a mask. Various compositions and methods for printing dielectrics, and methods of forming dielectric films therefrom are described in co-pending U.S. patent application Ser. Nos. 11/452,108, 11/818,078, 11/888,949, and 11/842,884 [Attorney Docket Nos. IDR0502, IDR0813, IDR0742, and IDR0982], filed on Jun. 12, 2006, Jun. 12, 2007, Aug. 3, 2007, and Aug. 21, 2007, respectively, the relevant portions of which are incorporated herein by reference.

The substrate may also include an exposed silicon-containing layer (e.g., one or more device electrodes, etc.). In exemplary embodiments, the layer containing silicon and/or germanium is formed on the substrate by printing techniques such as inkjet printing, gravure printing. The semiconductor layer may comprise silicon- and/or germanium-containing layer, formed from a silicon- and/or germanium-containing semiconductor ink or a silicon/germanium precursor ink. The semiconductor or silicon precursor ink may comprise one or more precursor compounds (e.g., a [doped] silicon-containing compound such as a [poly]silane or a [poly]silagermane, which may further include a [poly]germane and/or a dopant source) and a solvent in which the compounds are soluble or suspendable. Various exemplary semiconductor ink formulations suitable for use in the present method, and methods for making such ink formulations are described in co-pending U.S. patent application Ser. Nos. 10/616,147, 10/789,317, 11/452,108, 11/888,949 and 12/131,002, (Attorney Docket Nos. KOV-004, IDR0020, IDR0502, IDR0742 and IDR1263), filed on Jul. 8, 2003, Feb. 27, 2004, Jun. 12, 2006, Aug. 3, 2007, and May 30, 2008, respectively, the relevant portions of which are incorporated herein by reference. The silicon or silicon precursor layer may be printed in a predetermined pattern, avoiding or reducing the need for conventional photolithography and etching steps. Alternatively, the semiconductor layer may be deposited by conventional vapor deposition techniques (e.g. PECVD, MOCVD, LPCVD, Hot-wire CVD, sputtering, etc.) and patterned by conventional photolithography and etching.

The aluminum precursor ink formulation may be deposited over the substrate using any suitable deposition technique known in the art. For example, the ink may be deposited by coating or printing. Coating may include spin coating, dip-coating, spray-coating, slit coating, extrusion coating, meniscus coating, slide-bar coating, pump dispensing, syringe dispensing, microspotting and/or pen-coating the formulation. Printing may include inkjet printing, gravure printing, screen printing, offset printing, flexographic printing, vapor jetting, laser forward transfer or local laser CVD, laser writing, microspotting, spray coating, pump dispensing, stenciling, stamping, etc. The layer of ink may be deposited in a patterned or unpatterned layer. In preferred variations, a patterned layer may be formed by selective deposition techniques, such as inkjet printing, gravure printing, screen printing, or flexographic printing.

Preferable process conditions for inkjet printing the aluminum precursor ink composition may include a mass loading of 1-40 wt. % (e.g., 20-30 wt. %) of the aluminum precursor(s), an ink viscosity of 2-100 cP (e.g., 2-15 cP, or any other range of values therein), and a printing frequency of about 1-100 kHz (preferably 5-50 kHz, 10-25 kHz, or any other range of values therein). The contact angle between the printed ink and the substrate may be from 0° to about 90° (or any range of values therein).

The printing process may be conducted under an inert and/or reducing atmosphere. Thus, printing may include purging an atmosphere in which the substrate is placed, then introducing an inert and/or reducing gas into the atmosphere, prior to printing. In various embodiments, the inert and/or reducing gas may comprise He, Ar, N₂, etc., which may further comprise H₂, NH₃, SiH₄, and/or other source of gas-phase reducing agent (e.g., in an amount up to about 20 vol. %). The inert and/or reducing gas atmosphere may reduce any incidence of inadvertent and/or undesired oxide formation. In a preferred embodiment, the composition may be printed under an inert atmosphere (preferably with O₂ levels<<1 ppm) to avoid unacceptably high oxygen content in the formed films, which may result in poor device performance. In one embodiment, the inert atmosphere consists essentially of Ar, and may further include less than 0.1 ppm O₂ and less than 100 ppm N₂.

The printed aluminum metal precursor ink composition may be heated during and/or immediately after being printed or deposited onto the substrate. The substrate may be contemporaneously heated in accordance with a desired solvent evaporation rate (typically in a range of from 30° C. -90° C., depending on the solvent to be evaporated). In other embodiments, the ink and the substrate may be heated at a temperature and for a length of time sufficient to induce the aluminum metal precursor to decompose to form aluminum metal. Temperatures sufficient for decomposing the aluminum metal precursors are less than about 350° C. (e.g., about 100° C. to about 250° C., or any range of temperatures therein, preferably from about 100° C. to about 120° C.). The lengths of time for decomposing the aluminum metal precursors in the printed ink within these temperature ranges are from about 1 second to about 10 minutes, 10 seconds to about 5 minutes, or any range of times therein (e.g., from about 30 seconds to about 5 minutes, or about 1 minute to 3 minutes, etc.). Heating may take place on a conventional hotplate or in a conventional furnace or oven. Optionally, the heating may occur in an inert atmosphere as described above, and in co-pending U.S. patent application Ser. No. 11/888,949 (Attorney Docket No. IDR0742), filed Aug. 3, 2007, the relevant portions of which are incorporated herein by reference. Where the aluminum precursor ink also includes a promoter compound (e.g., one or more of TiCl₄, TiBr₄, SiCl₄, and Ti(OEt)₄, as described above in paragraphs [0030]-[0032]), decomposition may be induced at a temperature of about 18° C. to 40° C., with or without (UV) irradiation of the printed aluminum metal precursor ink.

Alternatively, during and/or immediately after printing or coating the aluminum precursor ink, decomposition of the aluminum metal precursors may be induced by photonic or actinic radiation to form an aluminum hydride polymer and/or aluminum metal. Thus, in one embodiment, the Al metal precursor(s) are decomposed by UV irradiation (e.g., light having a wavelength of <400 nm, e.g., about 240 nm), supplied by a mercury arc lamp, mercury vapor lamp, xenon flash lamp, or UV laser (e.g., a KrF or ArF excimer laser). The ink composition may be irradiated during and/or after the printing of the ink composition. The radiation dose may be in the range of 0.01 mJ/cm² to 25 J/cm² (in some embodiments, 0.01 mJ/cm² to 1.2 J/cm²), using a light source with a power output of about 0.1-15, 0.75-10 or 1-5 watt/cm² (or any other range of values therein). Additionally, the irradiation exposure may be used to pattern the aluminum metal precursor layer. For example, the layer of metal ink may be deposited as a continuous layer in accordance with some embodiments of the present invention (e.g., where the aluminum precursor ink is blanket deposited by spin-coating). In such embodiments, the metal layer may be patterned before the curing step by irradiating with a laser beam having a predetermined spot and/or beam width (e.g., “direct writing”). Thus, a patterned layer (e.g., metal electrode pattern) may be formed by a selective irradiating and curing process, in which a layer of dried metal ink is selectively cured in a pattern using a laser to write the pattern. In an alternative embodiment, the layer of metal ink can be cured by blanket or flood irradiation (e.g., from a mercury lamp) through a mask, wherein uncured regions of the metal ink layer can then be removed by techniques known in the art, such as development and/or selective etching.

In alternative embodiments, the substrate may be selectively pretreated with a promoter compound as described above (e.g., TiCl₄, TiBr₄, SiCl₄, and/or Ti(OEt)₄). Pretreatment with a promoter compound may comprise gas, vapor, and/or liquid phase deposition of the promoter compound using a mask (e.g., a photoresist), or the promoter compound may be selectively printed on the substrate. The aluminum precursor ink may then be deposited thereover. For example, the aluminum precursor ink may be deposited over a substrate by a coating method (e.g., spin-coating). In this embodiment, the promoter compound provides improved adhesion of the aluminum metal and nucleation and catalysis of the decomposition of the aluminum precursors in the coated ink, allowing for selective formation of aluminum metal in the areas of the substrate where the promoter compound was deposited. Alternatively, aluminum metal may be electrolessly plated over the substrate. In this embodiment, the promoter compound provides improved adhesion of the plated aluminum metal, allowing for selective formation of aluminum metal in the areas of the substrate where the promoter compound was deposited. Alternatively, the promoter may be coated on substantially the entire substrate, but the Al ink formulation is printed thereon. Thereafter (e.g., after curing the Al), the exposed promoter may subsequently be removed, for example by selective wet or dry etching.

After the aluminum precursor ink layer is deposited and substantially decomposed, the aluminum precursor ink layer may be cured at a first temperature to remove at least a portion of the remaining volatile solvent(s), ligand(s), and other materials and additives from the ink layer that have not been evaporated by previous heating and/or irradiation. Temperatures sufficient for removing solvents range from about 30° C. to about 150° C., or any range of temperatures therein (e.g., below about 100° C., preferably about 30 to 90° C.). The length of time may be sufficient to remove substantially all of the solvent and/or substantially all of the additive(s) from the coated or printed aluminum precursor ink (e.g., from 1 second to 4 hours, 1 minute to 120 minutes, or any other range of values therein). Heating may take place on a conventional hotplate or in a conventional furnace or oven. The solvent can be evaporated and the precursor film cured under an inert atmosphere (preferably Ar, rather than N₂) with O₂ levels<<1 ppm to avoid unacceptably high oxygen content in the formed films.

Additionally, the aluminum ink layer may be cured at a second temperature (e.g., above about 100° C. to about 350° C., or any range of temperatures therein, preferably from about 150° C. to about 250° C.) after curing at the first temperature to reduce, sinter, and/or further decompose the aluminum metal precursors and convert any remaining aluminum hydride polymer in the layer to form an aluminum metal layer (whether patterned or unpatterned). The second curing step may improve the adhesion of the aluminum metal to the underlying structure (e.g., a gate oxide).

Curing at the second temperature is generally carried out for a period of time sufficient to fuse or sinter the aluminum metal together and form a conductive aluminum metal film. The curing time generally ranges from about 1 minute to about 2 hours, or any range of values therein. In preferred embodiments, the aluminum ink layer is cured from about 10 minutes to about 1 hour (e.g., from about 10 to about 30 minutes).

In various embodiments, curing at the second temperature occurs in a furnace or oven, in an inert atmosphere. The curing processes can be performed in an inert atmosphere (preferably Ar, rather than N₂) with O₂ levels<<1 ppm, as described herein. The inert atmosphere may consist essentially of Ar, and may further include less than 0.1 ppm O₂ and less than 100 ppm N₂. For example, the metal ink may be deposited in and/or exposed to an inert atmosphere, and heated at a temperature ranging from greater than ambient temperature to about 100-35020 C., or 100-200° C., depending on the substrate. This process has particular advantages in embodiments where the substrate cannot be processed at a relatively high temperature (e.g., aluminum foil, a polycarbonate, polyethylene and polypropylene esters, a polyimide, etc.). A sealable oven, furnace, or rapid thermal annealing furnace configured with a vacuum source and reducing/inert gas sources may be used for providing the reducing atmosphere and heat (thermal energy) for heterogeneous reduction. In the alternative, the metal precursor film may be thermally decomposed to the elemental metal using a heat source (e.g., a hotplate) in an apparatus in which the atmosphere may be carefully controlled (e.g., a glove box or dry box). Such annealing/reducing processes, and alternatives thereof, are described in co-pending U.S. application Ser. Nos. 11/888,949 and 12/131,002 (Attorney Docket Nos. IDR0742 and IDR1263), respectively filed Aug. 3, 2007 and May 30, 2008, the relevant portions of which are incorporated by reference herein. In preferred embodiments, the present inks may form films with conductivities that are as high as 100% (e.g., 10 to 95%, 20 to 90%, or any other range of values therein) of the conductivity of bulk aluminum.

The aluminum layer formed using the methods described above may be applied to a device such as a thin film capacitor, a thin film transistor (e.g., a bottom-gate or a top-gate transistor), a diode (e.g., a Schottky diode, Zener diode, photodiode, etc.), a resistor, and/or circuitry incorporating the same, and/or a metal interconnects between devices. Exemplary TFTs, capacitors, diodes, etc., and methods of forming such electronic devices from metal inks are described below, and are also described in detail in co-pending U.S. patent application Ser. Nos. 12/175,450 and 12/243,880, respectively filed Jul. 17, 2008 and Oct. 1, 2008 (Attorney Docket Nos. IDR1052 and IDR1574, respectively), the relevant portions of which are incorporated herein by reference.

Exemplary Electronic Devices and Methods of Making the Same

Thin Film Transistors and Methods of Making the Same

In one aspect, the preset invention relates to a method of making a thin film transistor, comprising (a) forming a gate dielectric layer on or over a semiconductor feature on a substrate; and (b) forming an aluminum gate electrode over the gate dielectric layer. The semiconductor feature may include a doped patterned semiconductor layer, and forming the aluminum gate electrode preferably comprises printing and/or laser writing the aluminum metal layer forming the gate electrode. The TFT may comprise a doped semiconductor thin film, a device terminal layer above or below the semiconductor thin film, a gate electrode comprising an aluminum metal layer as described herein and/or other materials, and one or more metallization structures in contact with the doped semiconductor thin film, the device terminal layer, and/or the gate electrode. The gate electrode and/or the metallization structures are formed in the manner described above. In various embodiments, the doped semiconductor thin film may have a dome-shaped cross-sectional profile as described in detail in co-pending U.S. patent application Ser. No. 12/243,880, filed Oct. 1, 2008 (Attorney Docket No. IDR1574).

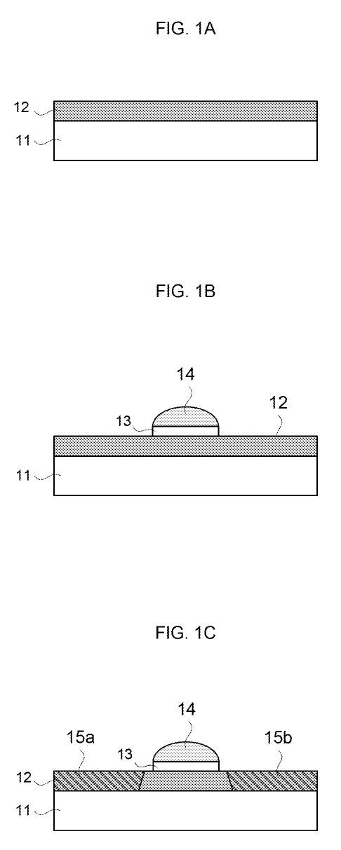

FIG. 1A shows a first step in the exemplary process. A semiconductor layer 12 is formed on an insulating substrate 11. For example, a doped or undoped silane composition may be deposited (e.g., by coating, printing, or inkjetting a silane ink) onto substrate 11 to form semiconductor layer 12 (see, e.g., U.S. patent application Ser. No. 10/616,147 [filed on Jul. 8, 2003, as Atty. Docket No. KOV-004], Ser. No. 10/789,317 [filed on Feb. 27, 2004, as Atty. Docket No. IDR0020], Ser. No. 10/789,317 [filed on Feb. 27, 2004, as Atty. Docket No. IDR0080], and/or Ser. No. 10/949,013 [filed on Sep. 24, 2004 as Atty. Docket No. IDR0302]). In such embodiments, the semiconductor layer 12 may have a dome-shaped cross-sectional profile as described in detail in co-pending U.S. patent application Ser. No. 12/243,880, filed Oct. 1, 2008 (Attorney Docket No. IDR1574). Alternatively, a layer of silicon (e.g., amorphous silicon) may be conventionally blanket-deposited (e.g., by chemical vapor deposition), patterned (e.g., by photolithography) and optionally crystallized (e.g., by annealing). In a further alternative, the semiconductor layer 12 may be omitted and gate dielectric layer 13 (see FIG. 1B) may be formed on the substrate 11, which may be a semiconductor material.

Referring back to FIG. 1A, substrate 11 may comprise a substrate material described above in paragraphs [0042]-[0047]. For example, substrate 11 may comprise a plastic sheet (e.g., a polyimide, polycarbonate, or other high temperature polymer), a thin glass sheet, a glass/polymer laminate, a metal foil, etc., having a low cost and ease of processing, relative to single crystal silicon substrates. In one embodiment, the substrate has properties (e.g., a thickness, tensile strength, modulus of elasticity, glass transition temperature, etc.) acceptable for roll-to-roll manufacturing (e.g., spool-based and/or roll-to-roll printing processes). Alternatively, substrate 11 may comprise an insulator (e.g., a spin on glass [SOG] or grown or anodized oxide layer) on a conducting or semiconducting substrate. Also, the insulator may be deposited onto or formed on a conventional metal foil (e.g., see U.S. patent application Ser. No. 10/885,283, filed Jul. 6, 2004 (Atty. Docket No. IDR0121), the relevant portions of which are incorporated herein by reference). FIG. 1A may also represent only a relatively small portion of the entire substrate 11, which may have one or more dimensions (e.g., width or diameter) considerably different (e.g., larger) than that shown in FIG. 1.

Referring now to FIG. 1B, a gate dielectric layer 13 is formed over the semiconductor layer 12. The gate dielectric layer 13 may be a conventional dielectric (e.g., silicon dioxide or silicon nitride formed by plasma enhanced chemical vapor deposition [PECVD], high density plasma CVD [HDPCVD], evaporation or ALD, or alternatively, a spin-on-glass [SOG], etc.), but it is preferably grown on semiconductor layer 12 (generally by heating, exposure to a plasma, or irradiating the structure in an oxidizing atmosphere, such as oxygen). The gate dielectric layer 13 is deposited and then may be conventionally patterned (e.g., by photolithography or printing a mask layer, and etching), such that the gate dielectric layer 13 between the semiconductor layer 12 and a gate electrode 14 has a substantially uniform width, as shown in FIG. 1B. Alternatively, the gate dielectric layer 13 may be selectively printed over predetermined areas of the semiconductor layer 12 (see, e.g., copending U.S. patent application Ser. Nos. 11/084,448 and 11/203,563 [Attorney Docket Nos. IDR0742 and IDR0813], filed on Mar. 18, 2005 and Aug. 11, 2005, respectively, the relevant portions of which are incorporated herein by reference). Specifically, the gate dielectric layer 13 may be printed in a predetermined area of the semiconductor layer 12 where a gate electrode 14 will be deposited. In such a case, the gate dielectric may have an initial width greater than that of the gate, then after printing the gate electrode 14, the gate dielectric layer 13 is etched back using the gate electrode 14 as a mask.

The gate dielectric layer 13 may have any thickness that is less than 1000 Å (e.g., from 20 Å to 400 Å from 30 to 300 Å, or from 50 to 200 Å, or any range of values less than 1000 Å). In cases where the gate dielectric 13 is formed by thermal oxidation of semiconductor layer 12, the gate dielectric layer 13 generally has a thickness that is less than 500 Å.

As shown in FIG. 1B, a gate electrode 14 may then be formed on the gate dielectric layer 13. In a preferred embodiment, gate electrode 14 is formed by printing (preferably inkjetting or gravure printing) an aluminum ink composition comprising an aluminum precursor in accordance with the descriptions above in paragraphs [0021]-[0033]. The printed ink is then heated and/or irradiated, and cured according to the methods described above.

Alternatively, the gate electrode 14 on gate dielectric 13 may be blanket deposited (e.g., by spin coating, spray coating, or a conventional CVD based deposition technique), and patterned by conventional photolithography or laser patterning (preferably by [i] coating a deposited metal layer with a thermal resist or other conventional resist containing an IR dye and [ii] selectively irradiating the resist with a laser; see, e.g., U.S. patent application Ser. No. 11/084,448 [Atty. Docket No. IDR0211], filed on Mar. 18, 2005, and Ser. No. 11/663,296 [Atty. Docket No. IDR0213], the relevant portions of which are incorporated herein by reference). In such an embodiment, the gate dielectric layer 13 generally extends across the entire exposed surface of the semiconductor layer 12. Removal of excess gate metal material by development of the resist and etching (preferably conventional wet etching) forms gate electrode 14.

In another alternative embodiment, one or more promoter compounds as described above in paragraphs [0030]-[0032] can be printed, coated, or deposited onto the gate dielectric layer 13 prior to depositing an aluminum ink to form gate electrode 14. In such a case, the aluminum precursor ink can be printed or coated over the promoter compound(s). The promoter compound(s) may catalyze the decomposition of aluminum precursors in the aluminum ink composition (after the ink is printed or coated onto the promoter compound[s]) during a subsequent heating and/or irradiation process, as described above. In a further alternative embodiment, Al metal can be electrolessly plated (e.g., from a bath comprising the aluminum hydride precursor) onto the dried and/or cured promoter compound to form the gate electrode 14.

Next, semiconductor regions 15a and 15b may be heavily doped with a first type of dopant (e.g., n-type or p-type), generally by conventional ion implantation or dopant diffusion (e.g., from a spin-on dopant source; see U.S. patent application Ser. No. 11/888,949, filed Aug. 3, 2007 [Attorney Docket No. IDR0742]) into the regions of semiconductor layer 12 not covered by gate electrode 14. Alternatively, a source/drain contact layer may be formed on the upper surface of semiconductor regions 15a-b by depositing a doped semiconductor composition onto the gate electrode 14 and exposed areas of semiconductor layer 12, then laser irradiating the doped semiconductor composition to selectively crystallize irradiated portions of the composition (and preferably activate dopant therein; see, e.g., U.S. patent application Ser. No. 11/084,448 [Atty. Docket No. IDR0211], filed on Mar. 18, 2005). Such doped semiconductor compositions may be selectively deposited by printing or inkjetting a doped silicon-containing formulation, such as an N+-doped or P+-doped silane ink (see U.S. patent application Ser. Nos. 10/949,013 and 12/175,450 [Attorney Docket Nos. IDR0302 and IDR1052, respectively], filed on Sep. 24, 2004, and Jul. 17, 2008, respectively, the relevant portions of each of which are incorporated herein by reference) onto the gate electrode 14 and exposed portions of semiconductor layer 12.

For instance, a spin-on dopant may be printed onto semiconductor layer 12 and gate electrode 14. Thereafter, the spin-on dopant is dried and cured. Next, the exposed portions of semiconductor layer 12 (or the substrate 11 in embodiments where semiconductor layer 12 is omitted) within a diffusion distance of the spin-on dopant are doped by annealing the spin-on dopant at a temperature and for a length of time sufficient to diffuse the dopant into semiconductor layer 12. The resulting regions of exposed, doped silicon 15a-b are illustrated in FIG. 1C.

To the extent heavily doped regions 15a-b comprise an amorphous Group IVA element-containing material (e.g., Si and/or Ge), one preferably crystallizes them before depositing the next layer. In one example, the doped semiconductor regions 15a-b are first cured by furnace annealing and then crystallized by laser crystallization. Preferably, some or substantially all of the dopant therein is activated during the annealing and/or crystallization.

Alternatively, dopant atoms may be introduced into or onto the exposed surfaces of semiconductor regions 15a-b by plasma deposition, laser decomposition, vapor deposition or other technique, after which the doped regions 15a-b are converted into source and drain contacts by annealing. In embodiments where the semiconductor layer 12 is excluded, the substrate 11 (which comprises a semiconductor material in such embodiments) can be doped in areas adjacent to the gate electrode 14 by conventional techniques (e.g., by forming a photoresist mask and performing ion implantation).

The present method may further include forming an interconnect wiring that forms an electrical connection with the semiconductor regions 15a-b and the gate electrode 14. Methods for forming an interconnect wiring are described below, and may be applied to the present embodiment for making a TFT. Where an interlayer dielectric layer is formed over the aluminum gate electrode 14 and patterned to expose the gate electrode 14, a silicide layer and/or a barrier layer (not shown) may be formed over the semiconductor regions 15a-b to prevent diffusion and/or reaction of silicon atoms from semiconductor regions 15a-b with the overlying metal interconnect (not shown). The silicide layer may comprise a conventional silicide, such as titanium silicide, tungsten silicide, palladium silicide, etc. The barrier layer may comprise a conventional barrier layer material, such as titanium nitride, titanium silicon nitride, tantalum nitride, tungsten nitride, etc. The metal for the silicide layer and/or the barrier layer may be conventionally deposited (e.g., by PECVD, LPCVD, ALD, or sputtering, then lithographic patterning) or printed to a thickness of about 10 to 200 Å, or any range of values therein (e.g., about 50 to 100 Å).

Exemplary Capacitors and Methods of Making the Same

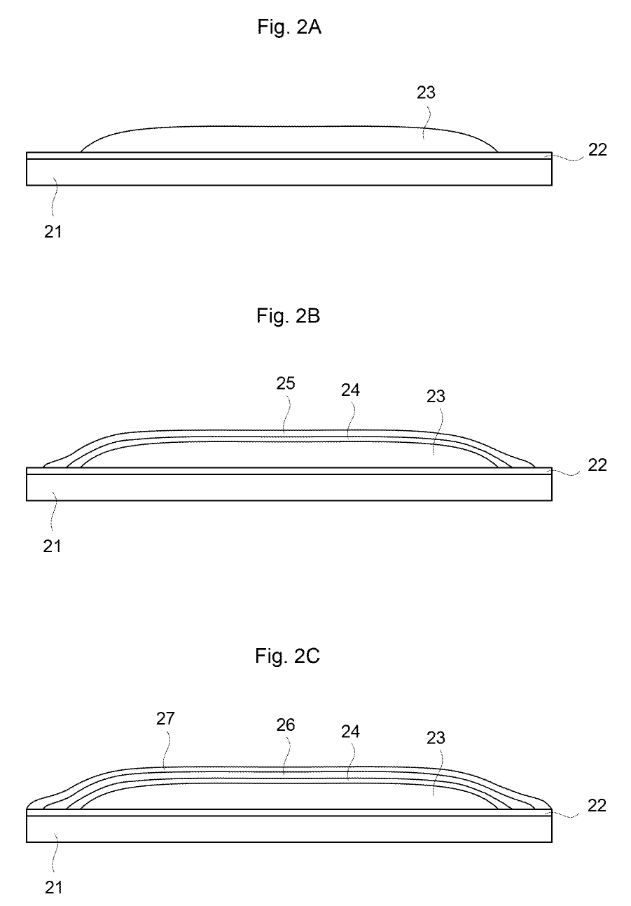

Another aspect of the present invention relates to thin film capacitors and methods of making a thin film capacitor (e.g., a metal-oxide-semiconductor [MOS] capacitor, or a metal-insulator-metal [MIM] capacitor), the steps of which are illustrated in FIGS. 2A-2C, which show cross-sectional views of exemplary thin film capacitors.

FIG. 2B shows an embodiment of a thin film capacitor. The exemplary thin film capacitor comprises a lower aluminum layer 23 (e.g., a lower capacitor plate, printed and/or deposited as described herein) formed over a substrate 21 having a dielectric layer 22 thereover. A dielectric layer 24 (e.g., an oxide layer, such as SiO₂ or Al₂O₃, a spin-on-glass [SOG], silicon nitride, an organic dielectric, etc.) covers the aluminum layer 23, and may be formed on aluminum layer 23. An upper aluminum layer 25 (printed and/or deposited as described herein) may be formed on the dielectric layer 24. The second aluminum layer 25 may form an upper capacitor plate, as shown in FIG. 2B. Alternatively, the upper capacitor plate 25 may comprise or consist essentially of a doped semiconductor layer 25. Generally, some portion of the lower capacitor plate 23 will not have the upper capacitor plate 25 or the dielectric layer 22 thereover. This allows for exposure of a portion of the lower capacitor plate 23 by removing part or all of the exposed capacitor dielectric 24, for formation of a contact/metal interconnect thereto.

Further structures may be included, as shown in FIG. 2C, which shows a non-linear embodiment of a thin film capacitor. Specifically, an upper layer 27 of aluminum as described above is formed on a doped semiconductor layer 26. Alternatively, the capacitor layers may be reversed (e.g., upper metal on oxide on doped silicon on lower metal). Further details regarding the exemplary thin film capacitor will be indicated in the following description of exemplary methods of forming the thin film capacitors shown in FIGS. 2B and 2C.

In general, the aluminum layer 23, as shown in FIG. 2A, is formed by printing or coating an aluminum precursor ink, as described above, on or over a substrate 21 that may have a thin buffer or dielectric layer 22 thereon, and drying and curing the ink, as described above. The dielectric layer 22 may be a conventionally grown or deposited oxide and/or nitride layer 22 (e.g., aluminum oxide, silicon dioxide, silicon nitride, etc.).

Alternatively, a promoter compound as described above can be printed, coated, or deposited onto the substrate 21 or the oxide and/or nitride layer 22 prior to depositing the aluminum precursor ink to form the aluminum layer 23. In such a case, the aluminum precursor ink can be printed or coated over the deposited promoter compound. In a further alternative embodiment, Al metal can be electrolessly plated onto the dried and/or cured promoter compound as described herein to form the aluminum layer 23.

In another alternative embodiment, the layer 23 may be a semiconductor layer (e.g., doped or undoped amorphous, hydrogenated silicon or polycrystalline silicon) formed by printing (e.g., inkjetting, screen printing or slit extruding) an ink composition comprising a semiconductor precursor (e.g., an oligo- and/or polysilane, a [cyclo]silane, a hetero[cyclo]silane, and/or silicon nanoparticles; see U.S. patent application Ser. No. 10/616,147 [filed on Jul. 8, 2003, as Atty. Docket No. KOV-004], Ser. No. 10/789,317 [filed on Feb. 27, 2004, as Atty. Docket No. IDR0020], Ser. No. 10/789,317 [filed on Feb. 27, 2004, as Atty. Docket No. IDR0080], and/or Ser. No. 10/949,013 [filed on Sep. 24, 2004 as Atty. Docket No. IDR0302], the relevant portions of which are hereby incorporated herein by reference). In such embodiments, the semiconductor layer 23 may have a dome-shaped cross-sectional profile as described in detail in co-pending U.S. patent application Ser. No. 12/243,880, filed Oct. 1, 2008 (Attorney Docket No. IDR1574), the relevant portions of which are hereby incorporated herein by reference. Alternatively, the semiconductor layer 23 may be formed by conventional methods (e.g., by evaporation, physical vapor deposition, sputtering of an elemental target, or chemical vapor deposition [e.g., PECVD, LPCVD], ALD, blanket deposition, evaporation, spin coating, etc., followed by patterning and development or etching).

The semiconductor precursor ink composition may further comprise a dopant (which may be B, P, As or Sb, but which is preferably B or P) in a concentration of from about 10¹⁶ to about 10²¹ atoms/cm³. Alternatively, dopant may be implanted into the semiconductor layer 25 after the semiconductor layer 25 has been deposited. Typical semiconductor layer 25 thicknesses may be from about 30, 75 or 100 nm to about 200, 500 or 1000 nm, or any range of values therein. The film thickness may be chosen to result in certain predetermined electrical properties for the capacitor.

Subsequently, as shown in FIG. 2B, a dielectric layer 24 is formed on the lower metal or semiconductor layer 23. In one embodiment, dielectric layer 24 comprises Al₂O₃, and is formed by anodic oxidation of an aluminum metal layer 23. Dielectric 24 may be formed by alternative techniques, as described above in paragraphs [0045]-[0046]. For instance, dielectric layer 24 may be formed by a conventional process (e.g., silicon dioxide or silicon nitride formed by plasma enhanced chemical vapor deposition [PECVD], high density plasma CVD [HDPCVD], evaporation or ALD, or alternatively, a spin-on-glass [SOG], etc.). The dielectric layer 24 may then be conventionally patterned (e.g., by photolithography or printing a mask layer, and etching). Alternatively, the dielectric layer 24 may be selectively printed over predetermined areas of the metal/semiconductor layer 23 (see, e.g., copending U.S. patent application Ser. Nos. 11/084,448 and 11/203,563 [Attorney Docket Nos. IDR0742 and IDR0813], filed on Mar. 18, 2005 and Aug. 11, 2005, respectively, the relevant portions of which are incorporated herein by reference). Specifically, the dielectric layer 24 may be printed in a predetermined area of the lower capacitor layer 23.

Where dielectric layer 24 is formed by oxidation, the resulting oxide has a substantially uniform thickness over the entire upper surface of lower aluminum layer 23. Dielectric 24 acts as an insulating layer, and is formed such that it covers lower aluminum layer 23 in areas over which a doped semiconductor layer 26 or an upper aluminum layer 27 will be formed. The dielectric 24 may have a thickness of from 20 Å to 400 Å or any range of values therein (e.g., from 30 to 300 Å, or from 50 to 200 Å, etc.). In alternative embodiments, where the lower capacitor electrode 23 is a semiconductor layer, the dielectric 24 may be formed by wet or dry thermal oxidation, or by other methods described above.

As shown in FIG. 2C, a semiconductor layer 26 may be formed on or over the dielectric layer 24 as described herein, preferably by printing an ink composition comprising a semiconductor precursor. Thereafter, an upper metal layer 27 (a second layer for the upper capacitor electrode or plate) may be formed on the semiconductor layer 26 (e.g., in the case of a nonlinear capacitor). In a preferred embodiment, second metal layer 27 is formed by printing (e.g., inkjetting) an aluminum precursor ink composition, as described above. Alternatively, the upper capacitor electrode or plate 26/27 may be formed by conventionally depositing and patterning (e.g., PECVD, LPCVD, ALD, sputtering, etc., and lithographic patterning) the semiconductor material (or a first metal) to form layer 26, and plating (e.g., electroplating or electrolessly plating) the metal layer 27 thereon, as described above.

Exemplary Diodes and Methods of Making the Same

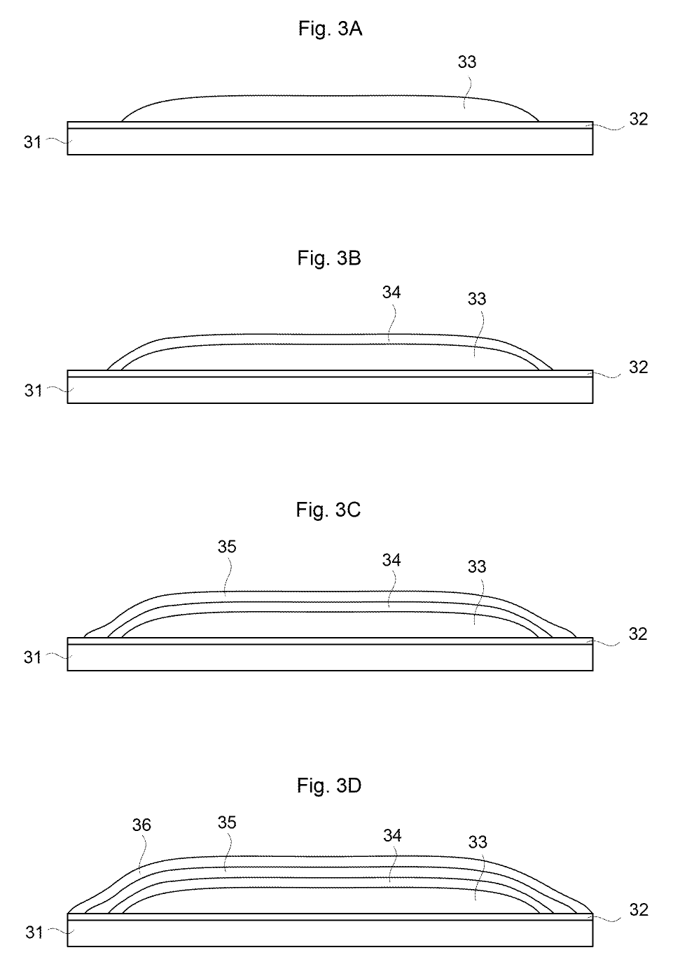

Another aspect of the present invention relates to thin film diodes and methods of making thin film diodes, exemplary steps of which are illustrated in FIGS. 3A-3D. In certain embodiments, the thin film diodes relate to Schottky diodes and methods of making the same. The methods disclosed herein are also capable of forming various types of diodes (e.g., p-n diodes, Zener diodes, etc. for use in image sensors, identification devices, wireless devices, etc.). Examples of diode structures and methods of making diodes that may be made using the present aluminum ink compositions and deposition techniques are disclosed in U.S. patent application Ser. Nos. 11/243,460, 11/452,108 and 11/888,949 (Attorney Docket Nos. IDR0272, IDR0502 and IDR0742, respectively), filed on Oct. 3, 2005, Jun. 12, 2006 and Aug. 3, 2007, respectively, and U.S. Pat. Nos. 7,152,804 and 7,528,017, the relevant portions of which are incorporated herein by reference.

FIG. 3C shows a cross-sectional view of an exemplary thin film diode (e.g., a Schottky diode). The exemplary thin film diode may comprise an aluminum layer 33 over a semiconductor substrate 31 (e.g., formed by printing, drying, and curing an aluminum precursor ink as described above) having a dielectric layer 32 thereon. Alternatively, layer 33 may comprise a heavily doped semiconductor layer, which preferably is a crystallized Group IVA element-containing material (e.g., Si and/or Ge). One or more lightly doped and preferably crystallized semiconductor layers 34 may be formed on the aluminum or heavily doped semiconductor layer 33. Alternatively, the semiconductor layer(s) 34 may comprise an intrinsic semiconductor layer or a heavily doped layer having a doping type complementary to that of semiconductor layer 33. A Schottky contact layer 35 comprising a metal silicide (e.g., palladium silicide, nickel silicide, cobalt silicide, tungsten silicide, titanium silicide, etc.) may be formed over the (lightly) doped semiconductor layers 34. A second aluminum layer 36 (see FIG. 3D) may be formed on the silicide layer 35. Further details regarding the exemplary thin film diode(s) will be indicated in the following description of exemplary method(s) of forming the thin film diode.

As shown in FIG. 3A, an exemplary method comprises forming or depositing (e.g., printing or coating) an aluminum precursor ink, as described above, on or over a substrate 31 that may have a thin buffer or dielectric layer 32 thereon, and drying and curing the ink, as described above. In the case where the substrate comprises a metal sheet and/or foil, the device may further comprise an inductor, a capacitor and/or one or more other devices, and the method may further comprise forming the inductor and/or capacitor from the metal substrate (see, e.g., U.S. Pat. No. 7,152,804 [Atty. Docket No. IDR0121] and U.S. Pat. No. 7,286,053 [Atty. Docket No. IDR0312] and U.S. patent application Ser. No. 11/243,460 [filed on Oct. 3, 2005, as Atty. Docket No. IDR0272] and Ser. No. 11/452,108 [filed on Jun. 12, 2006, as Atty. Docket No. IDR0502]).

The film thickness of the aluminum layer 33 may be chosen to optimize the electrical properties of the diode. Typical thicknesses for the aluminum layer 33 may be from about 10, 25, 50, or 100 nm to about 200, 500 or 1000 nm, or any range of values therein. In addition, the aluminum layer 33 may have a width of at least 1, 2, 5, or 10 μm, up to 50, 100, or 200 μm or more, or any range of values therein. The aluminum layer 33 may have a length (not shown in FIGS. 3A-3C) of at least 1, 2, 5, 10 or 20 μm, up to 20, 50 or 100 μm or more, or any range of values therein.

Alternatively, conductive layer 33 may be (or may comprise) a heavily doped semiconductor layer. Heavily doped semiconductor layer 33 is preferably formed by printing (e.g., inkjetting, screen printing, gravure printing, or slit extruding) a semiconductor ink composition (e.g., an ink comprising a [poly]silane) on or over the substrate 31 (including the dielectric layer 32), and then drying and curing and/or annealing the ink composition (see, e.g., U.S. Pat. No. 7,314,513 [Atty. Docket No. IDR0302] and U.S. Pat. No. 7,485,691 [Atty. Docket No. IDR0422], and U.S. patent application Ser. No. 10/616,147 [filed on Jul. 8, 2003, as Atty. Docket No. KOV-004], Ser. No. 10/789,317 [filed on Feb. 27, 2004, as Atty. Docket No. IDR0020], Ser. No. 10/789,317 [filed on Feb. 27, 2004, as Atty. Docket No. IDR0080], and/or Ser. No. 11/867,587 [filed on Oct. 4, 2007, as Atty. Docket No. IDR0884], the relevant portions of which are hereby incorporated herein by reference). In such embodiments, the semiconductor layer 33 may have a dome-shaped cross-sectional profile as described in detail in co-pending U.S. patent application Ser. No. 12/243,880 (filed Oct. 1, 2008, as Attorney Docket No. IDR1574). Alternatively, the semiconductor layer 33 may be formed by conventional methods (e.g., by evaporation, physical vapor deposition [e.g., sputtering], chemical vapor deposition [e.g., PECVD, LPCVD, etc.], ALD, spin coating, etc.). The semiconductor ink composition may further comprise a dopant (which may comprise a B, P, As or Sb source or compound) in a concentration of from about 10¹⁶ to about 10²¹ atoms/cm³. Alternatively, dopant may be implanted into the semiconductor layer 33 after it has been deposited. Typical semiconductor layer thicknesses may be from about 30, 75 or 100 nm to about 200, 500 or 1000 nm, or any range of values therein. The film thickness may be chosen to optimize the electrical properties of the diode.

After deposition, the ink composition may be dried and cured to form an amorphous, hydrogenated doped or undoped semiconductor (e.g., a-Si:H) layer. After curing is performed, the heavily doped semiconductor layer 33 may be partially or substantially completely crystallized to form a doped or undoped polycrystalline (e.g., polysilicon) film. In one embodiment, crystallization may comprise irradiating with a laser (e.g., laser crystallization, which may also activate some or all of the dopant in the thin film, if present). The heavily doped semiconductor layer 33 is preferably crystallized before subsequently depositing further layers.

As shown in FIG. 3B, one or more lightly doped (e.g., N⁻-doped, P⁻-doped) or intrinsic semiconductor layers 34 may be deposited or printed over aluminum (or heavily doped semiconductor) layer 33. Lightly doped semiconductor layers 34 (preferably one semiconductor layer) may be formed in accordance with the techniques for depositing semiconductor layers disclosed above. In various embodiments, the lightly doped semiconductor layers 34 may comprise or consist essentially of a lightly doped semiconductor material, such as one or more Group IVA elements (e.g., silicon and/or germanium), which may further contain an n-type dopant (such as P, As, or Sb) or a p-type dopant (such as B or Ga) in a concentration of from ˜10¹⁶ to ˜5×10⁸ atoms/cm³. Alternatively, one may conventionally deposit, dope and pattern the lightly doped semiconductor layer 34.

Typical thicknesses for the one or more lightly doped semiconductor layers 34 may be from about 10, 25, 50, or 100 nm to about 200, 500 or 1000 nm, or any range of values therein. The film thickness may be chosen to optimize the electrical properties of the diode. In addition, the lightly doped semiconductor layer 34 may have a width of at least 1, 2, 5, or 10 μm, up to 50, 100, or 200 μm or more, or any range of values therein. The one or more lightly doped semiconductor layers 34 may have a length (not shown in FIGS. 3A-3C) of at least 1, 2, 5, 10 or 20 μm, up to 20, 50 or 100 μm or more, or any range of values therein.

The lightly doped semiconductor layer 34 may be then crystallized (and preferably, some or substantially all of the dopant therein activated) by furnace annealing or laser crystallization. The printed (or deposited) semiconductor layers 34 (and heavily doped semiconductor layer 33 in certain embodiments), and may be further (re)crystallized by sequential lateral solidification (SLS) and/or laser crystallization to improve carrier mobility. If desired, a substantially similar, but relatively heavily doped (or complementarily doped) semiconductor layer may be formed on the lightly doped semiconductor layer 34, substantially as described herein.

As shown in FIG. 3C, a Schottky contact may be formed by depositing a silicide-forming metal on or over the semiconductor layer(s) 34. When the semiconductor layer(s) 34 comprise an uppermost silicon-containing layer, annealing the silicide-forming metal and the semiconductor layer(s) 34 forms a metal silicide layer 35. An ink including a silicide-forming metal (e.g., a metal precursor ink) can be printed, coated or selectively deposited on the semiconductor layer(s) 34 (see, e.g., co-pending U.S. patent application Ser. Nos. 12/131,002 and 12/175,450, filed May 30, 2008, and Jul. 17, 2008, respectively [Attorney Docket Nos. IDR1263 and IDR1052, respectively]). In various implementations, the metal of the silicide-forming metal precursor ink is selected from the group consisting of Pd, Pt, Ni, Co, Cr, Mo, W, Ru, Rh, Ti and alloys/mixtures thereof. The ink is then dried to remove solvent(s) and/or additives, thereby forming a silicide-forming metal precursor. A subsequent anneal in a reducing or inert atmosphere (e.g., either nitrogen or a forming gas, such as an Ar/H₂ mixture) cures the ink and allows for the reaction between the metal precursor and silicon to form a silicide. The silicide-forming metal and the surface of the semiconductor layers 34 are heated to a first temperature for a length of time sufficient to form a metal silicide. The temperature range may be from 100° C. to about 1000° C. (e.g., from about 200° C. to about 800° C., or any range of values therein, such as from 450° C. to about 600° C., depending on the substrate 31). The heating time to form the silicide may be from 1 minute to about 24 hours (e.g., from 2 minutes to about 240 minutes, or any range of values therein, such as from about 10 to about 120 minutes).

Alternatively, silicide layer 35 may be formed by conventional techniques, such as depositing a metal by sputter deposition or electron beam evaporation. In a further alternative, a seed metal layer may be printed or otherwise deposited or formed on exposed surfaces of the semiconductor layer(s) 34, and a conductive metal may be selectively plated, deposited or printed thereon (optionally with subsequent thermal treatment or annealing to form a metal silicide) to form the silicide layer 35.

As shown in FIG. 3D, an aluminum metal layer 36 may then be formed on or over the silicide layer 35, generally by printing or depositing an aluminum precursor ink composition over the silicide layer 35 in accordance with the techniques described above. Preferably, aluminum layer 36 is selectively printed on or over the silicide layer as described herein.

In the disclosed embodiments, at least part of the aluminum layer (or heavily doped semiconductor layer) 33 remains exposed after formation of the lightly doped semiconductor layer(s) 34, silicide layer 35, and aluminum layer 36, to facilitate forming a contact and/or metal interconnect to the aluminum (or heavily doped semiconductor) layer 33.

In an alternative embodiment, a promoter compound as described above can be printed, coated, or deposited onto the silicide layer 35 prior to depositing an aluminum ink to form aluminum metal layer 36. In such a case, the aluminum precursor ink can be printed (e.g., inkjetted) or coated (e.g., spin coated) on or over (or electrolessly plated onto) the deposited promoter compound, as described herein.

It is well within the ability of one of ordinary skill in the art to make other types of diodes based on the disclosure herein. For example, N-i-P and P-i-N diodes (where “i” refers to an intrinsic semiconductor layer), N—P and P—N diodes, and variations thereof (e.g., P—N⁻—N⁺ diodes) where at least one of the N and P layers comprises a relatively lightly doped sublayer and a relatively heavily doped sublayer, any of which may have an overlying and/or underlying metal layer thereon and/or thereunder, are contemplated. Also, the exemplary transistors described herein can be readily configured as diodes if a source/drain terminal (e.g., the source) of the transistor is electrically connected to its gate using a metal interconnect, as described herein.

Exemplary Interconnect Wiring and Methods of Making the Same

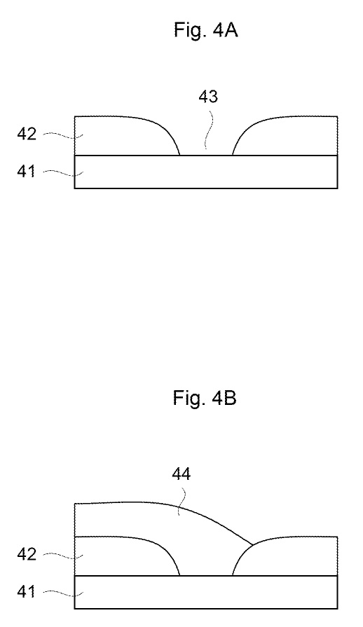

Another aspect of the present invention relates to an aluminum interconnect and/or aluminum wiring, and methods of making the same, the steps of which are illustrated in FIGS. 4A-4B, which show cross-sectional views of exemplary an aluminum interconnect and/or aluminum wiring. FIG. 4B shows an exemplary aluminum metal interconnect 44 over an interlayer dielectric layer 42. The interlayer dielectric layer 42 is over an electrically active layer 41, which may be a layer of one or more devices (e.g., a gate electrode, a capacitor electrode, a diode, etc.) formed using materials and techniques described herein or as otherwise known in the art. Alternatively, electrically active layer 41 may comprise an aluminum or other metal interconnect, formed conventionally or as described herein.

As shown in FIG. 4A, the exemplary method comprises forming or depositing an interlayer dielectric layer 42 over an electrically active layer 41. Dielectric layer 42 may be formed by a method as described above, including gas-phase deposition (e.g., CVD, PECVD, high density plasma [HDP] CVD, ALD, sputtering, evaporation, etc.), or liquid-phase deposition (e.g., see copending U.S. patent application Ser. Nos. 11/452,108, 11/818,078, 11/888,949, 11/842,884 and 12/109,338 [Attorney Docket Nos. IDR0502, IDR0813, IDR0742, IDR0982 and IDR1322], filed on Jun. 12, 2006, Jun. 12, 2007, Aug. 3, 2007, Aug. 21, 2007, and Apr. 24, 2008, the relevant portions of which are incorporated herein by reference). Preferably, the dielectric layer 42 may be selectively printed on over predetermined areas of the layer 41. Specifically, the dielectric layer 42 and openings therein may be printed in a predetermined area of the layer 41 and the substrate supporting layer 41, for instance exposing regions of electrical devices where aluminum interconnect 44 will form contacts (see, e.g., U.S. patent application Ser. No. 12/109,338 [Attorney Docket No. IDR1322], filed on Apr. 24, 2008, the relevant portions of which are incorporated herein by reference). The dielectric layer 42 may have a thickness, for example, of at least 0.1 μm, and preferably from 0.5 to 25 μm, 1 to 10 μm, or any range of values therein.

Subsequently, if dielectric layer 42 is not printed with contact holes or vias 43 therein, contact holes or vias 43 may be formed by conventional photolithography, laser irradiation of thermal resists, or printed resist lithography patterning, followed by a conventional dielectric etch. Suitable techniques for forming a dielectric layer with holes or openings therein are described in U.S. Pat. No. 7,286,053 and in co-pending U.S. patent application Ser. Nos. 11/888,949, 12/175,450, and 12/249,735, respectively filed on Aug. 3, 2007, Jul. 17, 2008, and Oct. 10, 2008 (Attorney Docket Nos. IDR0742, IDR1052, and IDR1412, respectively), the relevant portions of each of which are incorporated herein by reference. In such embodiments, the holes 43 may be subsequently widened by etching or other techniques known in the art.

After the dielectric layer 42 and contact holes 43 are formed, the aluminum precursor ink composition described above may be deposited (e.g., by printing) in the contact holes 43 and on selected areas of the surface of the dielectric layer 42. Alternatively, the aluminum precursor ink composition can be coated, blanket deposited, or deposited in another manner as described herein on or over the dielectric layer 42 and into the contact holes or vias 43. The aluminum precursor ink composition may be deposited to a thickness, for example, of from 0.5 to 10 μm, or any range of values therein (e.g., from 0.75 to 8 μm, from 1 to 5 μm, etc.). The aluminum metal layer 44 may be formed by heating, irradiating, and/or curing the dried Al ink, as described herein.

Since the device layer to which the aluminum metal forms a contact may be a silicon-containing layer, a lower silicon barrier layer (not shown) may be formed over the device layer 41 prior to deposition of the aluminum precursor ink. The barrier layer may comprise a conventional barrier layer material, such as titanium nitride, tantalum nitride, tungsten nitride, etc. The barrier layer may be conventionally deposited (e.g., by PECVD, LPCVD, ALD, sputtering, etc.) and patterned conventionally (e.g., lithography) to a thickness of about 10 to 200 Å, or any range of values therein (e.g., about 50 to 100 Å).

In such embodiments, further dielectric layers and metallization may be formed over the aluminum metal layer 44 to form further integrated circuitry. Accordingly, additional dielectric layers (having contact holes) and metallization layers may be formed in an alternating sequence (see, e.g., U.S. Pat. No. 7,286,053 and co-pending U.S. forming patent application Ser. Nos. 11/888,949, 12/175,450, 12/243,880, and 12/249,735, respectively filed on Aug. 3, 2007, Jul. 17, 2008, Oct. 1, 2008, and Oct. 10, 2008 [Attorney Docket Nos. IDR0742, IDR1052, IDR1574, and IDR1412, respectively). Other structures and/or features in addition to the aluminum metal interconnect may be formed thereon (e.g., contacts, pads for facilitating communications with external devices, etc.). As used herein, integrated circuits/circuitry includes all circuits that have a plurality of transistors, diodes, or other semiconductor devices interconnected by one or more layers of metallization thereon, such as identification tags, wireless devices, RF devices, HF devices, VHF devices, UHF devices, sensors, circuits for “smart” cards and other “smart” applications, and display, photovoltaic, and flexible circuits.

Also, after formation of the integrated circuitry is substantially complete, the present method may further comprise the step of passivating the integrated circuitry and/or the device (e.g., forming a passivation or dielectric layer over the integrated circuitry). The passivation layer generally inhibits or prevents the ingress of water, oxygen, and/or other species that could cause the degradation or failure of the integrated circuitry or device, and may add some mechanical support to the device, particularly during further processing. The passivation layer may be formed by conventionally coating the upper surface of the integrated circuitry and/or device with one or more inorganic barrier layers such as a polysiloxane; a nitride, oxide and/or oxynitride of silicon and/or aluminum; and/or one or more organic barrier layers such as parylene, a fluorinated organic polymer, or other barrier material. Alternatively, the passivation layer may further comprise a plurality of dielectric layers, an underlying layer of which may comprise a material having lower stress than an overlying layer. See, e.g., U.S. Pat. No. 7,286,053 and co-pending U.S. patent application Ser. Nos. 11/243,460, 11/888,949, 12/175,450, 12/243,880, and 12/249,735, respectively filed on Oct. 3, 2005, Aug. 3, 2007, Jul. 17, 2008, Oct. 1, 2008, and Oct. 10, 2008 (Attorney Docket Nos. IDR0272, IDR0742, IDR1052, IDR1574, and IDR1412 respectively).

### CONCLUSION/SUMMARY

The present invention concerns aluminum precursor ink compositions for use in printed electronics processes, methods of making such aluminum precursor ink compositions, and methods of forming aluminum metal layers with high conductivity (e.g., electrodes, gates, etc.) using such inks. Specifically, embodiments of the present invention pertain to forming conductive layers in integrated circuit devices by printing an aluminum metal precursor ink and decomposing the precursor(s) with heat and/or radiation to form an aluminum metal layer. The present ink composition simplifies and increases efficiency in the fabrication of printed integrated circuits, because the printing of conductive layers eliminates or reduces reliance on time-consuming, expensive conventional deposition and lithographic processing techniques. Additionally, by forming transistor gates and other structures by printing or coating the aluminum inks, silicon crystallization and dopant activation using ultraviolet (UV) lasers in areas adjacent to the aluminum film can be carried out without extra masks, since an aluminum film formed from the aluminum ink generally has a low absorbance and a high reflectivity for UV laser wavelengths. In addition, the ink formulations described herein may be used in conventional (i.e., non-printed) processing schemes.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A metal ink composition comprising:
a) an Al metal precursor in an amount of at least 1% by weight of the ink composition; and
b) a solvent in which the Al metal precursor is soluble, in an amount of at least 10 wt % of the ink composition.

2. The metal ink composition of claim 1, wherein the Al metal precursor comprises an aluminum hydride compound.

3. The metal ink composition of claim 2, wherein the aluminum hydride compound comprises compounds and/or complexes having the formula [(R¹)_{y}A]ₓAl(R²)₃, where A is a Group VA element or a Group VI element; x is 1 or 2; y is 2 or 3; and each instance of R¹ and R² is independently H or a linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group, or two R¹ groups taken together with the A atom form an aliphatic or aromatic cyclic ring.

4. The metal ink composition of claim 3, wherein A is O, S, Se, Te, N, P, As, or Sb.

5. The metal ink composition of claim 3, wherein R¹ and R² are each independently H or a C₁-C₄ alkyl group.

6. The metal ink composition of claim 3, wherein the Al metal precursor comprises an aluminum hydride complex with a monoalkyl-, dialkyl-, or trialkylamine.

7. The metal ink composition of claim 3, wherein x is 2, A in one instance is phosphorous and in a second instance is nitrogen, R² is H, and each instance of R¹ is independently H or a linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group.

8. The metal ink composition of claim 3, wherein A is O, R² is H, and each instance of R¹ is independently H or a linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group, or two R¹ groups taken together with the A atom form an aliphatic cyclic ring.

9. The metal ink composition of claim 1, wherein the ink composition further comprises an adhesion promoting agent.

10. The metal ink composition of claim 9, wherein the adhesion promoting agent comprises at least one compound of the formula M₁Xₙ, wherein M₁ is Si or a metal selected from the group consisting of Hf, Nb, V, Ta, Zr, and Ti; n is 2, 3, 4, or 5; and each instance of X is independently F, Cl, Br, I, O, or a pseudohalide.

11. The metal ink composition of claim 9, wherein the adhesion promoting agent comprises a metal alkoxide and/or a metal amide.

12. The metal ink composition of claim 1, wherein said metal ink composition comprises 1-25% by weight of said Al metal precursor.

13. The metal ink composition of claim 1, wherein the metal ink composition comprises about 25% to 99% of the solvent by weight.

14. The metal ink composition of claim 1, wherein the metal ink composition has a viscosity of from 2 to 100 cP.

15. The metal ink composition of claim 1, wherein the solvent comprises a C₅-C₁₂ alkane; a C₄-C₁₂ alkene; a C₄-C₁₂ alkyne; a C₆-C₁₄ aromatic hydrocarbon, an ether; a polyether; a methicone solvent; an amine having from one to three C₁-C₁₂ alkyl groups; a C₄-C₂₀ cyclic or alicyclic ether; a C₆-C₁₂ monocycloalkane, which may be substituted with from 1 to 2q C₁-C₄ alkyl or from 1 to q C₁-C₄ alkoxy substituents, where q is the number of carbon atoms in the monocycloalkane ring; C₁₀-C₁₂ bicycloalkanes; substituted or unsubstituted C₁₀-C₁₄ polycycloalkanes; or mixtures thereof.

16. A method of making a metal ink composition, comprising:
a) combining an Al metal precursor in an amount of at least 1% by weight of said composition and a solvent in an amount of at least 10% by weight of said composition in a vessel; and
b) mixing said Al metal precursor and said solvent until said composition is substantially homogeneous.

17. The method of claim 16, wherein the Al metal precursor comprises a substituted or unsubstituted aluminum hydride compound.

18. The method of claim 17, wherein the aluminum hydride comprises a compound and/or complex having the formula [(R¹)_{y}A]ₓAl(R²)₃, where A is a Group VA element or a Group VI element; x is 1 or 2; y is 2 or 3; and each instance of R¹ and R² is independently H or linear or branched C₁-C₆ alkyl, C₂-C₆ alkenyl, C₂-C₆ alkynyl, C₃-C₈ cycloalkyl, C₄-C₈ cycloalkenyl, C₆-C₁₀ aryl, or C₇-C₁₂ aralkyl group, or two R¹ groups taken together with the A atom form an aliphatic or aromatic cyclic ring.

19. The method of claim 16, wherein said metal ink composition comprises 1-25% by weight of said Al metal precursor.

20. The method of claim 16, wherein said metal ink composition comprises 1-10% by weight of said Al metal precursor.

21. The method of claim 16, further comprising adding an adhesion promoting agent to said composition.

22. The method of claim 16, wherein the solvent comprises a C₅-C₁₂ alkane; a C₄-C₁₂ alkene; a C₄-C₁₂ alkyne; a C₆-C₁₄ aromatic hydrocarbon, an ether; a polyether; a methicone solvent; an amine having from one to three C₁-C₁₂ alkyl groups; a C₄-C₂₀ cyclic or alicyclic ether; a C₆-C₁₂ monocycloalkane, which may be substituted with from 1 to 2q C₁-C₄ alkyl or from 1 to q C₁-C₄ alkoxy substituents, where q is the number of carbon atoms in the monocycloalkane ring; C₁₀-C₁₂ bicycloalkanes; substituted or unsubstituted C₁₀-C₁₄ polycycloalkanes; or mixtures thereof.

23. The method of claim 16, wherein the solvent comprises about 25% to 99% of the metal ink composition by weight.

24. The method of claim 16, wherein the metal ink composition has a viscosity of from 2 to 100 cP.

25. A method for forming a patterned metal film comprising:
a) depositing an Al metal precursor on a substrate in a predetermined pattern; and
b) converting said Al precursor to an Al metal.

26. The method of claim 25, wherein depositing the Al metal precursor comprises printing an aluminum precursor ink comprising the Al metal precursor and a solvent in the predetermined pattern on the substrate.

27. The method of claim 25, wherein converting said Al precursor to said Al metal comprises irradiating the deposited Al precursor with UV radiation having a wavelength of about 200 nm to 450 nm.

28. The method of claim 27, wherein the metal ink is irradiated within about 0.1 to about 10 seconds of printing.

29. The method of claim 27, wherein the metal ink is deposited and irradiated essentially simultaneously.

30. The method of claim 25, further comprising substantially evaporating the solvent.

31. The method of claim 30, wherein converting the Al metal precursor and substantially evaporating the solvent are carried out substantially simultaneously.

32. The method of claim 25, wherein converting said precursor to the metal layer comprises curing the printed the Al metal precursor.

33. The method of claim 32, wherein curing the printed the Al metal precursor comprises heating the substrate to a temperature of at least about 100° C.

34. The method of claim 25, wherein the substrate further comprises a semiconductor thin film thereon.

35. The method of claim 25, further comprising printing, coating, or depositing a promoter compound onto the substrate prior to depositing the Al metal precursor.

36. The method of claim 35, wherein the promoter compound is printed in the pattern, and depositing the Al metal precursor comprises immersing the substrate with the promoter compound thereon in a bath containing the Al metal precursor.

37. A method of making a thin film transistor, comprising
a) forming a gate dielectric layer on or over a semiconductor feature on a substrate; and
b) forming an aluminum gate electrode over the gate dielectric layer by the method of claim 25.

38. A method of making a semiconductor device, comprising
a) forming a semiconductor feature on a substrate; and
b) forming an aluminum metal feature on or over semiconductor feature by the method of claim 25.
